(19) United States
(12) Patent Application Publication
(10) Pub. No.: US 2018/0116046 A1
(43) Pub. Date: Apr. 26, 2018

(54) DISPLAY PANEL AND DISPLAY TERMINAL

(71) Applicant: Wuhan China Star Optoelectronics Technology Co. Ltd., Wuhan, Hubei (CN)

(72) Inventors: Yucheng LU, Shenzhen, Guangdong (CN); Hongrui CAO, Shenzhen, Guangdong (CN)

(73) Assignee: Wuhan China Star Optoelectronics Technology Co. Ltd., Wuhan, Hubei (CN)

(21) Appl. No.: 15/118,863

(22) PCT Filed: Jun. 23, 2016
(86) PCT No.: PCT/CN2016/086812

§ 371 Date: Aug. 13, 2016

(30) Foreign Application Priority Data
May 27, 2016 (CN) 201610367996.9

(51) Int. Cl. H05K 1/02; H05K 5/00; H01R 12/79

(52) U.S. Cl. CPC H05K 1/0216; H05K 5/0017; H05K 2201/0715; H01R 12/79; H05K 1/028

(57) ABSTRACT

A display panel and a display terminal are disclosed. The display panel includes a display, a main board, and a FPC board connecting the display and the main board together. The FPC board has a portion of its surface attached with an EMI shielding layer. At least an edge of the EMI shielding layer is an edge with curves. The FPC board simplifies the assembly of the display panel, reduces production cost and maintenance inconvenience, and contributes to the display panel's downsizing. The EMI shielding layer prevents noises of different frequency ranges from affecting the display signals. The at least one edge with curves of the EMI shielding layer lessens stress between and therefore protects the EMI shielding layer and the FPC board from damages.

### BACKGROUND OF THE INVENTION

### 1. Field of the Invention

The present disclosure generally relates to displays, and particularly relates to a display panel and a display terminal.

### 2. The Related Arts

Flexible printed circuit (FPC) board is a type of printed circuit board using polymide (PI) or polyester film as base material. FPC boards provides high reliability, excellent flexibility, and superior electrical performance, and therefore is capable of satisfying demands for even smaller form factor and higher density. FPC boards may also simplify assembly process and enhance reliability. FPC boards therefore become the mainstream solution to the miniaturization and mobility requirement of electronic appliances. FPC boards may be bended, rolled, folded up to millions of times without damaging the circuit. They may also be arranged freely to fit layout demands in a three-dimensional space to achieve an integral solution to component installation and connectivity. FPC boards may significantly reduce the volumes and weights of electronic appliances, and they are ideal for achieving high density, miniaturization, and high reliability.

When the electronic appliances operate, noises of various frequencies are produced may be produced, and these noises may interfere the display signals. To reduce these interferences, an electro-magnetic interference (EMI) layer is formed on an FPC board so as to shield the FPC board from noise interferences.

However, the EMI layer usually fails to entirely cover the FPC board, and some exposures may be present along the edges of the EMI layer. The exposures may lead to bending to the FPC board, causing damages to the internal circuit.

### SUMMARY OF THE INVENTION

The technical issue addressed by the present disclosure is to provide a display panel and a display terminal with means to prevent electro-magnetic interference without leading to potential damages to the flexible printed circuit board and the display panel.

To resolve the above technical issue, the present disclosure teaches a display panel including a display, a main board, and a flexible printed circuit (FPC) board. The FPC board has a first edge connected to the display and a second edge connected to the main board. Each major side of the FPC board has a portion of the surface attached with an electro-magnetic interference (EMI) shielding layer. At least one of the EMI shielding layer's edges adjacent to the first and second edges of the FPC board is an edge with curves.

The edge with curves is a wave-shape edge.

The FPC board is bended around the first edge so that the main board is disposed behind the display.

The FPC board is connected to at least an electronic component of the display panel. The electronic component is one of a microphone, a speaker, an earphone socket, a power socket, and a data port.

The FPC board is electrically connected to the main board through a connector.

To resolve the above technical issue, the present disclosure teaches another display panel including a display, a main board, and a FPC board connecting the display and the main board together. The FPC board has a portion of its surface attached with an EMI shielding layer. At least an edge of the EMI shielding layer is an edge with curves.

The FPC board has a first edge connected to the display and a second edge connected to the main board. At least one of the EMI shielding layer's edges adjacent to the first and second edges of the FPC board is an edge with curves.

The edge with curves is a wave-shape edge.

The FPC board is bended around the first edge so that the main board is disposed behind the display.

Each major side of the FPC board has a portion of the surface attached with the EMI shielding layer.

The FPC board is connected to at least an electronic component of the display panel. The electronic component is one of a microphone, a speaker, an earphone socket, a power socket, and a data port.

The FPC board is electrically connected to the main board through a connector.

To resolve the above technical issue, the present disclosure teaches a display terminal including a display panel. The display panel includes a display, a main board, and a FPC board connecting the display and the main board together. The FPC board has a portion of its surface attached with an EMI shielding layer. At least an edge of the EMI shielding layer is an edge with curves.

The FPC board has a first edge connected to the display and a second edge connected to the main board. At least one of the EMI shielding layer's edges adjacent to the first and second edges of the FPC board is an edge with curves.

The edge with curves is a wave-shape edge.

The FPC board is bended around the first edge so that the main board is disposed behind the display.

Each major side of the FPC board has a portion of the surface attached with the EMI shielding layer.

The FPC board is connected to at least an electronic component of the display panel. The electronic component is one of a microphone, a speaker, an earphone socket, a power socket, and a data port.

The FPC board is electrically connected to the main board through a connector.

The advantages of the present disclosure are as follows. The display panel of the present disclosure adopts a FPC board to connect the display and the main board together, and the FPC board has a portion of its surface attached with an EMI shielding layer having at least an edge with curves. The FPC board simplifies the display panel's assembly, lowers its production cost, provides convenient maintenance, and contributes to the downsizing of the display panel. The EMI shielding layer effective reduces EMI to display signals by noises of various frequency ranges when the display panel is operating. The at least one edge with curves of the EMI shielding layer lessens stress between and therefore protects the EMI shielding layer and the FPC board from damages.

### BRIEF DESCRIPTION OF THE DRAWINGS

To make the technical solution of the embodiments according to the present disclosure, a brief description of the drawings that are necessary for the illustration of the embodiments will be given as follows. Apparently, the drawings described below show only example embodiments of the present disclosure and for those having ordinary skills in the art, other drawings may be easily obtained from these drawings without paying any creative effort. In the drawings:

FIG. 1 is a schematic diagram showing a display panel according to a first embodiment of the present disclosure;

FIG. 2 is a schematic diagram showing a display panel according to a second embodiment of the present disclosure;

FIG. 3 is a schematic profile diagram showing a display panel according to a third embodiment of the present disclosure;

FIG. 4 is a schematic profile diagram showing a display panel according to a fourth embodiment of the present disclosure; and

FIG. 5 is a schematic diagram showing a display terminal according an embodiment of the present disclosure.

### DETAILED DESCRIPTION OF THE PREFERRED EMBODIMENTS

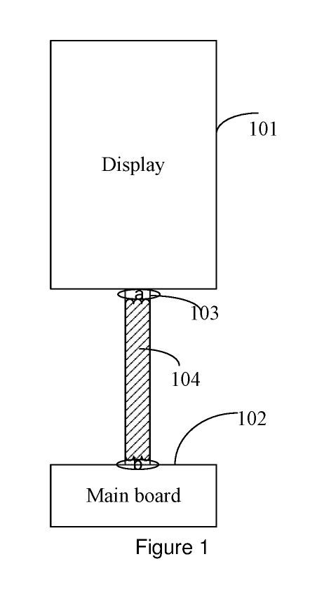

FIG. 1 is a schematic diagram showing a display panel according to a first embodiment of the present disclosure. As illustrated, the display panel includes a display 101 and a main board 102 controlling the display 102. The display 101 and the main board 102 are connected together through a flexible printed circuit (FPC) board 103. The FPC board 103 simplifies the assembly of the display panel, reduces production cost and maintenance inconvenience, and contributes to the display panel's downsizing.

To reduce the display panel's various noises of different frequency ranges affecting the display signals, at least a portion of the FPC board 103's surface is attached with an electro-magnetic interference (EMI) shielding layer 104. In a preferred embodiment, at least a side of the FPC board 103 has all the exposed area attached with the EMI shielding layer 104.

The EMI shielding layer 104 and the FPC board 103 may be damaged along their edges, due to excessive stress resulted from the attachment between the EMI shielding layer 104 and the FPC board 103, or from the FPC board 103's bending. To prevent this problem, in the present embodiment, the EMI shielding layer 104 has at least an edge with curves or, specifically, the EMI shielding layer 104 has at least a wave-shaped edge. Through the wave-like shape, excessive stress is effectively released, and the FPC board 103 and the EMI shielding layer 104 are protected.

Specifically, in the present embodiment, the FPC board 103 has a first edge (a) connected to the display 101 and a second edge (b) connected to the main board 102. The EMI shielding layer 104 then has one or both its edges adjacent to the first and second ends (a) and (b) of the FPC board 103 formed into a wave-like shape.

Alternative embodiments may also have the edges of the EMI shielding layer 104 formed into other irregular shapes with smooth curves. The present disclosure is not limited by what is depicted in the drawings.

Alternative embodiments may also have all edges of EMI shielding layer 104 formed into a wave-like shape so as to protect the FPC board 103 and the EMI shielding layer 104 along all directions.

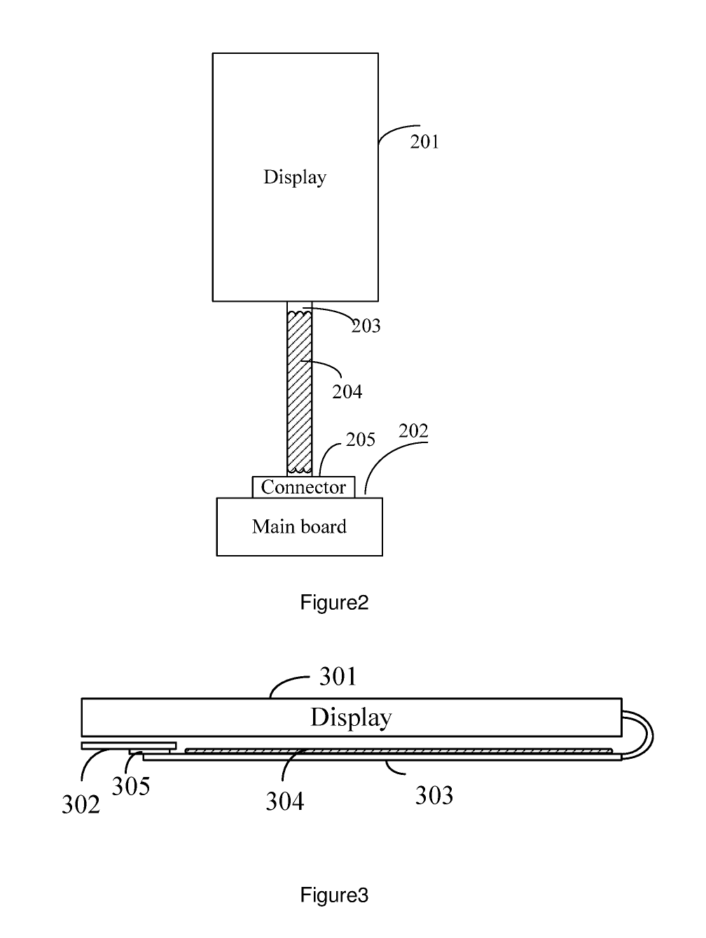

FIG. 2 is a schematic diagram showing a display panel according to a second embodiment of the present disclosure. In the present embodiment, the FPC board 203 is connected to the main board 202 through a connector 205.

FIG. 3 is a schematic profile diagram showing a display panel according to a third embodiment of the present disclosure. In the present embodiment, to further reduce the form factor of the display panel, the FPC board 303 is bended around the first edge (a) connecting the display 301 so that the FPC board 303 is disposed behind the display 301, significantly reducing the consumed space inside the display panel.

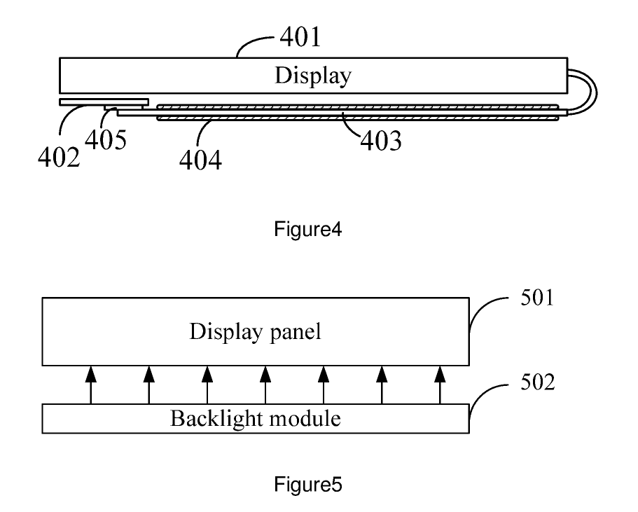

FIG. 4 is a schematic profile diagram showing a display panel according to a fourth embodiment of the present disclosure. In the present embodiment, to further enhance the EMI shielding performance, the FPC board 403 has a portion of both major sides' surfaces attached with EMI shielding layers 404. Each EMI shielding layer 404 has at least an edge with curves or, more specifically, a wave-like edge.

In an alternative embodiment, the display panel further includes an electronic circuit configured to a bottom side of the display panel. The electronic circuit includes at least one of a microphone, a speaker, an earphone socket, a power socket, and a data port. These components are connected to the main board of the display panel through the FPC board. Not only connectivity among the components is achieved, but also the display panel is thinner and lighter.

Compared to the prior art, the display panel of the present disclosure adopts a FPC board to connect the display and the main board together, and the FPC board has a portion of its surface attached with an EMI shielding layer having at least an edge with curves. The FPC board simplifies the display panel's assembly, lowers its production cost, provides convenient maintenance, and contributes to the downsizing. The EMI shielding layer effective reduces EMI to display signals when the display panel is operating. The at least one edge with curves of the EMI shielding layer lessens stress between and therefore protects the EMI shielding layer and the FPC board from damages.

FIG. 5 is a schematic diagram showing a display terminal according an embodiment of the present disclosure. The display terminal may be a smart phone, a smart TV, a PC, a tablet computer, or other device having a display panel.

The display terminal includes a display panel 501 and a backlight module 502. The display panel 501 is disposed on a top side of the backlight module 502. The backlight module 502 provides illumination to the display panel 501.

The display panel 501 includes a display and a main board controlling the display. The display and the main board is connected together through a FPC board. The FPC board simplifies the display panel's assembly, lowers its production cost, provides convenient maintenance, and contributes to the downsizing.

To reduce the display panel 501's various noises of different frequency ranges affecting the display signals, at least a portion of the FPC board's surface is attached with an EMI shielding layer. In a preferred embodiment, at least a side of the FPC board 103 has all the exposed area attached with the EMI shielding layer.

The EMI shielding layer and the board 103 may be damaged along their edges due to excessive stress resulted from the attachment between the EMI shielding layer and the FPC board, or from the FPC board's bending. To prevent this problem, in the present embodiment, the EMI shielding layer has at least an edge with curves or, specifically, the EMI shielding layer has at least a wave-shaped edge. Through the wave-like shape, excessive stress is effectively released, and the FPC board and the EMI shielding layer are protected.

Specifically, in the present embodiment, the FPC board has a first edge connected to the display and a second edge connected to the main board. The EMI shielding layer then has one or both its edges adjacent to the first and second edges (a) and (b) of the FPC board formed into a wave-like shape.

Alternative embodiments may also have the edges of the EMI shielding layer 104 formed into other irregular shapes with smooth curves. The present disclosure is not limited by what is depicted in the drawings.

Alternative embodiments may also have all edges of EMI shielding layer 104 formed into a wave-like shape so as to protect the FPC board 103 and the EMI shielding layer 104 along all directions.

In alternative embodiments, the FPC board is connected to the main board through a connector.

In alternative embodiments, to further reduce the form factor of the display panel 501, the FPC board is bended around the first edge connecting the display so that the FPC board is disposed behind the display, significantly reducing the consumed space inside the display panel 501.

In alternative embodiments, to further enhance the EMI shielding performance, the FPC board has a portion of both major sides' surfaces attached with EMI shielding layers. Each EMI shielding layer has at least an edge with curves or, more specifically, a wave-like edge.

In an alternative embodiment, the display panel 501 further includes an electronic circuit configured to a bottom side of the display panel 501. The electronic circuit includes at least one of a microphone, a speaker, an earphone socket, a power socket, and a data port. These components are connected to the main board of the display panel 501 through the FPC board. Not only connectivity among the components is achieved, but also the display panel 501 is thinner and lighter.

Compared to the prior art, the display terminal of the present disclosure includes a display panel that adopts a FPC board to connect the display and the main board together, and the FPC board has a portion of its surface attached with an EMI shielding layer having at least an edge with curves. The FPC board simplifies the display panel's assembly, lowers its production cost, provides convenient maintenance, and contributes to the downsizing. The EMI shielding layer effective reduces EMI to display signals when the display panel is operating. The at least one edge with curves of the EMI shielding layer lessens stress between and therefore protects the EMI shielding layer and the FPC board from damages.

Embodiments of the present disclosure have been described, but not intending to impose any unduly constraint to the appended claims. Any modification of equivalent structure or equivalent process made according to the disclosure and drawings of the present disclosure, or any application thereof, directly or indirectly, to other related fields of technique, is considered encompassed in the scope of protection defined by the claims of the present disclosure.

What is claimed is:

1. A display panel, comprising a display, a main board, and a flexible printed circuit (FPC) board, wherein the FPC board has a first edge connected to the display and a second edge connected to the main board; each major side of the FPC board has a portion of the surface attached with an electro-magnetic interference (EMI) shielding layer; at least one of the EMI shielding layer's edges adjacent to the first and second edges of the FPC board is an edge with curves.

2. The display panel as claimed in claim 1, wherein the edge with curves is a wave-shape edge.

3. The display panel as claimed in claim 1, wherein the FPC board is bended around the first edge so that the main board is disposed behind the display.

4. The display panel as claimed in claim 1, wherein the FPC board is connected to at least an electronic component of the display panel; and the electronic component is one of a microphone, a speaker, an earphone socket, a power socket, and a data port.

5. The display panel as claimed in claim 1, wherein the FPC board is electrically connected to the main board through a connector.

6. A display panel, comprising a display, a main board, and a FPC board connecting the display and the main board together, wherein the FPC board has a portion of its surface attached with an EMI shielding layer; and at least an edge of the EMI shielding layer is an edge with curves.

7. The display panel as claimed in claim 6, wherein the FPC board has a first edge connected to the display and a second edge connected to the main board; and at least one of the EMI shielding layer's edges adjacent to the first and second edges of the FPC board is an edge with curves.

8. The display panel as claimed in claim 7, wherein the edge with curves is a wave-shape edge.

9. The display panel as claimed in claim 7, wherein the FPC board is bended around the first edge so that the main board is disposed behind the display.

10. The display panel as claimed in claim 6, wherein each major side of the FPC board has a portion of the surface attached with the EMI shielding layer.

11. The display panel as claimed in claim 6, wherein the FPC board is connected to at least an electronic component of the display panel; and the electronic component is one of a microphone, a speaker, an earphone socket, a power socket, and a data port.

12. The display panel as claimed in claim 6, wherein the FPC board is electrically connected to the main board through a connector.

13. A display terminal, comprising a display panel, wherein the display panel comprises a display, a main board, and a FPC board connecting the display and the main board together; the FPC board has a portion of its surface attached with an EMI shielding layer; and at least an edge of the EMI shielding layer is an edge with curves.

14. The display terminal as claimed in claim 13, wherein the FPC board has a first edge connected to the display and a second edge connected to the main board; and at least one of the EMI shielding layer's edges adjacent to the first and second edges of the FPC board is an edge with curves.

15. The display terminal as claimed in claim 14, wherein the edge with curves is a wave-shape edge.

16. The display terminal as claimed in claim 13, wherein the FPC board is bended around the first edge so that the main board is disposed behind the display.

17. The display terminal as claimed in claim 13, wherein each major side of the FPC board has a portion of the surface attached with the EMI shielding layer.

18. The display terminal as claimed in claim 13, wherein the FPC board is connected to at least an electronic component of the display panel; and the electronic component is one of a microphone, a speaker, an earphone socket, a power socket, and a data port.

19. The display terminal as claimed in claim 13, wherein the FPC board is electrically connected to the main board through a connector.
